(19) United States
(12) Patent Application Publication
(10) Pub. No.: US 2013/0203334 A1
(43) Pub. Date: Aug. 8, 2013

(54) CONTAINER DATA CENTER

(71) Applicant: CHAO-KE WEI, Tu-Cheng (TW)

(72) Inventor: CHAO-KE WEI, Tu-Cheng (TW)

(73) Assignee: HON HAI PRECISION INDUSTRY CO., LTD., Tu-Cheng (TW)

(21) Appl. No.: 13/452,953

(22) Filed: Apr. 23, 2012

(30) Foreign Application Priority Data
Feb. 2, 2012 (TW) 101103438

(51) Int. Cl. H05K 5/02

(52) U.S. Cl. 454/184

(57) ABSTRACT

A container data center includes a container and an airflow guide cover. The container includes an end wall defining an opening. The airflow guide cover is mounted to the end wall and includes a plate covering the opening. A vent is defined in the plate. A hollow airflow guide portion protrudes into the container from an inner surface of the plate, surrounding the vent.

### BACKGROUND

1. Technical Field

The present disclosure relates to a container data center.

2. Description of Related Art

Container data centers are centralized computing facilities, and include a number of information processing devices installed in the container. They may also have a plurality of shutters installed on the container for ventilation purpose. During operation, the information processing devices generate a great amount of heat in the container, and most hot air in the container is dissipated out through the shutters. However, some of the hot air is blocked by the shutters and flow back in the container.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawing, all the views are schematic, and like reference numerals designate corresponding parts throughout the several views.

FIG. 1 is an assembled, isometric view of an exemplary embodiment of a container data center.

FIG. 2 is a partial, exploded, isometric view of the container data center of FIG. 1, wherein the container data center includes an airflow guide cover.

FIG. 3 is an enlarged view of the airflow guide cover of FIG. 2 from another perspective.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

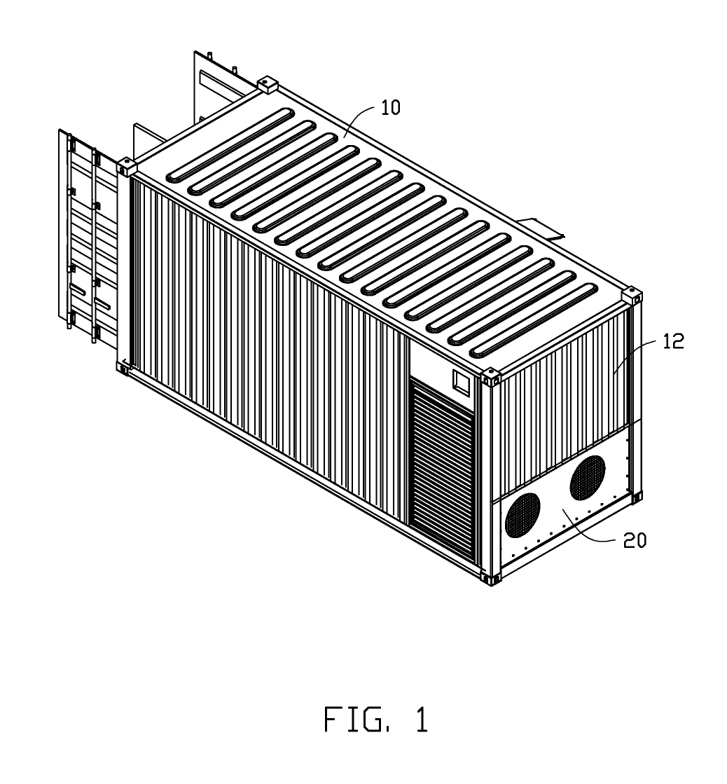

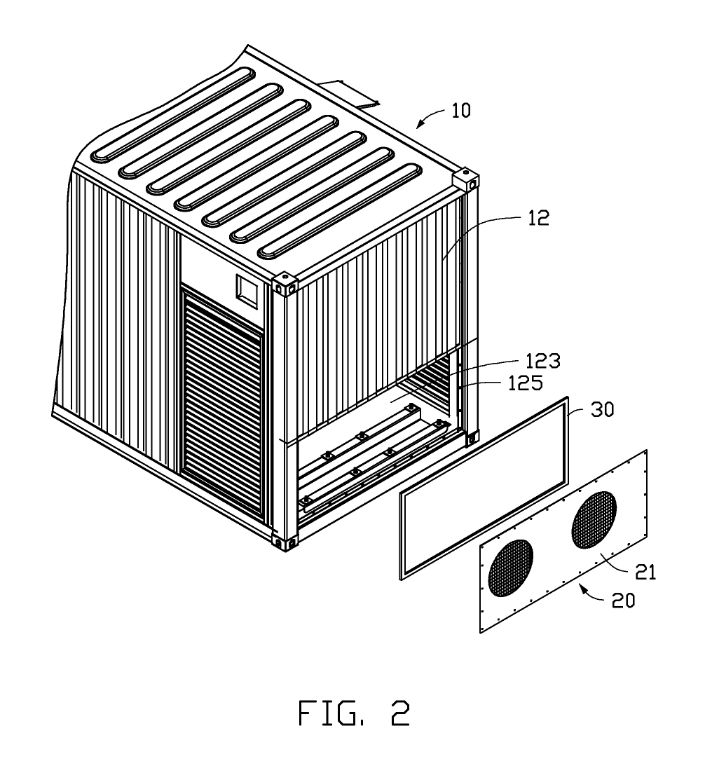

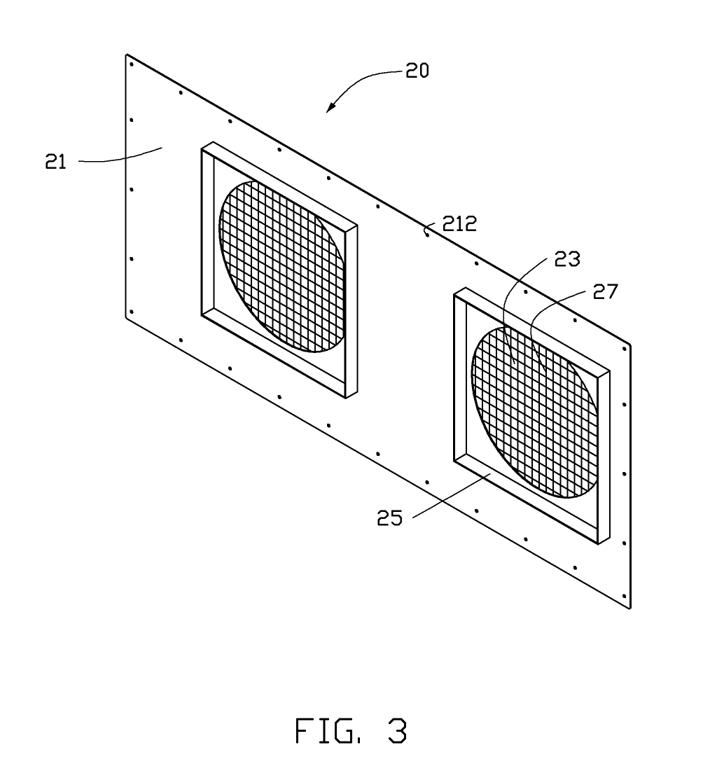

FIGS. 1 to 3, show an exemplary embodiment of a container data center including a container 10, an airflow guide cover 20, and a shockproof member 30.

The container 10 includes an end wall 12. A rectangular opening 123 is defined in the end wall 12. A plurality of threaded holes 125 is defined in the end wall 12 around the opening 123.

The airflow guide cover 20 includes a rectangular plate 21. Two spaced vents 23 are defined in the plate 21. Two hollow airflow guide portions 25 protrude from the inner surface of the plate 21. Each airflow guide portion 25 surrounds a corresponding one of the vents 23. Two dust-proofing screens 27 are mounted to the plate 21, respectively covering the vents 23. A plurality of through holes 212 is defined in the plate 21, adjacent to four edges of the plate 21.

In the embodiment, the shockproof member 30 is a rectangular hollow frame made of foam. In other embodiments, the shockproof member 30 can be a rectangular hollow frame made of rubber, or a plurality of resilient pads made of foam or rubber.

In assembly, the shockproof member 30 is stuck to the outer surface of the end wall 12 around the opening 123, or stuck to the inner surface of the plate 21 around four edges of the plate 21. The airflow guide cover 20 covers the opening 123, to allow the through holes 212 to respectively align with the threaded holes 125. A plurality of screws are respectively extended through the through holes 212 and engaged in the corresponding threaded holes 125. Thereby, the airflow guide cover 20 is fixed to the end wall 12. The shockproof member 30 is sandwiched between the end wall 12 and the plate 21, which can absorb shock between the airflow guide cover 20 and the container 10.

In use, hot air in the container 10 is directed by fans to pass through the airflow guide portions 25 and out of the container 10 through the vents 23. The airflow guide portions 25 can guide hot air out of the container 10, and prevent from hot air flowing back in the container 10.

Even though numerous characteristics and advantages of the embodiments have been set forth in the foregoing description, together with details of the structure and the functions of the embodiments, the disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A container data center, comprising:
a container comprising an end wall defining an opening; and
an airflow guide cover mounted to the end wall and comprising a plate covering the opening, wherein a vent is defined in the plate, and a hollow airflow guide portion protrudes into the container from an inner surface of the plate, surrounding the vent.

2. The container data center of claim 1, wherein a shockproof member is sandwiched between the end wall and the plate, surrounding the opening.

3. The container data center of claim 2, wherein the shockproof member is stuck to an outer surface of the end wall around the opening, or stuck to the inner surface of the plate around four edges of the plate.

4. The container data center of claim 3, wherein the shockproof member is a hollow frame made of foam.

5. The container data center of claim 3, wherein the shockproof member is a hollow frame made of rubber.

6. The container data center of claim 3, wherein the shockproof member is a plurality of resilient pads made of foam or rubber.
